(19) United States
(12) Patent Application Publication
(10) Pub. No.: US 2025/0120095 A1
(43) Pub. Date: Apr. 10, 2025

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Jinwoo Lee, Suwon-si (KR); Geonhui Han, Pohang-si (KR); Hyunsang Hwang, Pohang-si (KR); Dongho Ahn, Suwon-si (KR); Jinmyung Choi, Suwon-si (KR)

(73) Assignees: SAMSUNG ELECTRONICS CO., LTD., Suwon-si (KR); POSTECH RESEARCH AND BUSINESS DEVELOPMENT FOUNDATION, Pohang-si (KR)

(21) Appl. No.: 18/802,058

(22) Filed: Aug. 13, 2024

(30) Foreign Application Priority Data
Oct. 6, 2023 (KR) 10-2023-0133630
Dec. 26, 2023 (KR) 10-2023-0191851

(51) Int. Cl. H10B 63/00

(52) U.S. Cl. CPC H10B 63/34; H10B 63/845

(57) ABSTRACT

A semiconductor device includes a substrate, source/drain regions on the substrate, a channel layer between the source/drain regions and including indium gallium zinc oxide (IGZO), a variable resistance layer on the channel layer and including metal oxide that satisfies a stoichiometric ratio of metal to oxygen, a gate insulating layer on the variable resistance layer and including metal oxide that does not satisfy the stoichiometric ratio of metal to oxygen, and a gate electrode on the gate insulating layer.

### CROSS-REFERENCE TO RELATED APPLICATION

This application is based on and claims priority under 35 U.S.C. § 119 to Korean Patent Application No. 10-2023-0133630, filed on Oct. 6, 2023, in the Korean Intellectual Property Office, and Korean Patent Application No. 10-2023-0191851, filed on Dec. 26, 2023, in the Korean Intellectual Property Office, the disclosure of which is incorporated by reference herein in its entirety.

### BACKGROUND

The inventive concept relates to a semiconductor device and an electronic system including the same. More particularly, the inventive concept relates to a semiconductor device having a variable resistance layer and an electronic system including the same.

Electronic systems including data storage demand a semiconductor device capable of storing high-capacity data. Accordingly, methods capable of increasing the data storage capacity of a semiconductor device have been researched. For example, as one of the methods of increasing the data storage capacity of a semiconductor device, a semiconductor device including three-dimensionally arranged memory cells instead of two-dimensionally arranged memory cells has been proposed.

### SUMMARY

The inventive concept provides a semiconductor device with an improved retention characteristic.

According to some embodiments of the inventive concept, there is provided a semiconductor device including a substrate, source/drain regions on the substrate, a channel layer between the source/drain regions and including indium gallium zinc oxide (IGZO), a variable resistance layer on the channel layer and including a first metal oxide that satisfies a stoichiometric ratio of metal to oxygen, a gate insulating layer on the variable resistance layer and including a second metal oxide that does not satisfy the stoichiometric ratio of metal to oxygen, and a gate electrode on the gate insulating layer.

According to some embodiments of the inventive concept, there is provided a semiconductor device including a substrate, a gate stack on the substrate, including a plurality of insulating layers and a plurality of gate electrodes alternately stacked in a vertical direction that is perpendicular to a top surface of the substrate, and having a through hole that extends into the plurality of insulating layers and the plurality of gate electrodes in the vertical direction, and a pillar structure inside the through hole, wherein the pillar structure includes a gate insulating layer in the through hole and including a first metal oxide that does not satisfy a stoichiometric ratio of metal to oxygen, a variable resistance layer on an inner wall of the gate insulating layer in the through hole and including a second metal oxide that satisfies the stoichiometric ratio of metal to oxygen, a channel layer on an inner wall of the variable resistance layer inside the through hole and including IGZO, and a buried insulating layer in a central region of the through hole.

According to some embodiments of the inventive concept, there is provided an electronic system including a main substrate, a semiconductor device on the main substrate, and a controller on the main substrate and electrically connected to the semiconductor device, wherein the semiconductor device includes a gate stack on a substrate, including a plurality of insulating layers and a plurality of gate electrodes alternately stacked in a vertical direction that is perpendicular to a top surface of the substrate, and having a through hole that extends into the plurality of insulating layers and the plurality of gate electrodes in the vertical direction, and a pillar structure in the through hole, wherein the pillar structure includes a gate insulating layer in the through hole and including a first metal oxide that does not satisfy a stoichiometric ratio of metal to oxygen, a variable resistance layer on an inner wall of the gate insulating layer in the through hole and including a second metal oxide that satisfies the stoichiometric ratio of metal to oxygen, a channel layer on an inner wall of the variable resistance layer in the through hole and including IGZO, and a buried insulating layer in a central region of the through hole.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view illustrating a semiconductor device according to some embodiments;

FIG. 2 is a graph obtained by measuring a hysteresis appearing in a semiconductor device;

FIG. 3 is a block diagram illustrating a semiconductor device according to some embodiments;

FIG. 4 is an equivalent circuit diagram of a memory cell array in a semiconductor device according to some embodiments;

FIG. 5 is a cross-sectional view illustrating a semiconductor device according to some embodiments;

FIG. 6 is a magnified cross-sectional view of a portion EX of FIG. 5;

FIG. 7 is a cross-sectional view illustrating a program operation of a semiconductor device according to some embodiments;

FIG. 8 is a cross-sectional view illustrating an erase operation of a semiconductor device according to some embodiments;

FIGS. 9, 10, 11, and 12 are cross-sectional views illustrating a method of manufacturing a semiconductor device according to some embodiments;

FIG. 13 is a block diagram schematically illustrating an electronic system including a semiconductor device according to some embodiments;

FIG. 14 is a perspective view schematically illustrating an electronic system including a semiconductor device according to some embodiments; and

FIG. 15 is a cross-sectional view schematically illustrating a semiconductor package according to some embodiments.

### DETAILED DESCRIPTION

Hereinafter, embodiments are described in detail with reference to the accompanying drawings. Like reference numerals in the drawings denote like elements, and thus their repetitive description will be omitted.

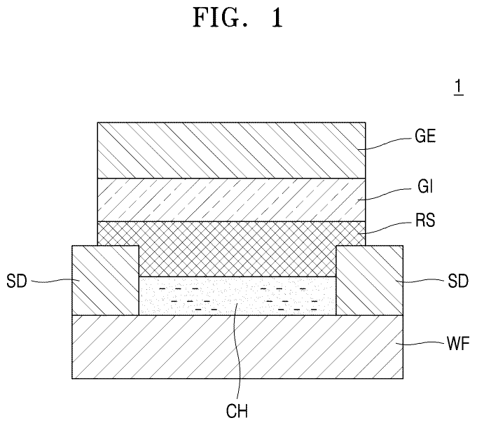

FIG. 1 is a cross-sectional view illustrating a semiconductor device 1 according to some embodiments.

Referring to FIG. 1, the semiconductor device 1 may include a substrate WF, a channel layer CH, a variable resistance layer RS, a gate insulating layer GI, and a gate electrode GE. The channel layer CH, the variable resistance layer RS, the gate insulating layer GI, and the gate electrode GE may form one transistor.

The substrate WF may include a semiconductor material, e.g., a Group IV semiconductor, a Group III-V compound semiconductor, or a Group II-VI oxide semiconductor. For example, the Group IV semiconductor may include silicon (Si), germanium (Ge), or SiGe.

The channel layer CH may be on the upper surface of the substrate WF. In some embodiments, the channel layer CH may include a metal oxide semiconductor material. For example, the channel layer CH may include indium gallium zinc oxide (IGZO). The channel layer CH may include a single layer made of a metal oxide semiconductor material or a plurality of layers made of metal oxide semiconductor materials. Because the channel layer CH is made of a metal oxide semiconductor material, such as IGZO, the off-current of a transistor including the channel layer CH may decrease and the on/off current ratio of the transistor may increase.

A source/drain SD may be on the substrate WF and at both sides of the channel layer CH. For example, a source may be at one side of the channel layer CH and a drain may be at the other side of the channel layer CH that is opposite to the one side of the channel layer CH at which the source is arranged. The source/drain SD may be electrically connected to the channel layer CH. In some embodiments, the source/drain SD may include a conductive material. For example, the source/drain SD may include a metal, a metal compound, impurity-doped polysilicon, or a conductive polymer.

The variable resistance layer RS may be on the source/drain SD and the channel layer CH. The variable resistance layer RS may fully cover or fully overlap the upper surface of the channel layer CH and cover or overlap at least portions of the upper surfaces of the source/drain SD. In some embodiments, the variable resistance layer RS may include metal oxide that satisfies a stoichiometric ratio. The metal oxide may include at least one of, for example, rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and/or manganese oxide. For example, the variable resistance layer RS may include tungsten oxide, where the ratio of tungsten (W) to oxygen in the tungsten oxide is about 1:3 and may satisfy the stoichiometric ratio. In some embodiments, the variable resistance layer RS may include a material of which the activation energy for movement of oxygen included in the variable resistance layer RS is 0.5 eV or lower.

The gate insulating layer GI may be on the variable resistance layer RS. The gate insulating layer GI may have the same horizontal area as the variable resistance layer RS. In some embodiments, the gate insulating layer GI may include metal oxide that does not satisfy the stoichiometric ratio. The metal oxide may include at least one of, for example, rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and/or manganese oxide. For example, the gate insulating layer GI may include hafnium oxide, where the ratio of hafnium to oxygen in the hafnium oxide is about 1:1.7 and may not satisfy the stoichiometric ratio. That is, the gate insulating layer GI may include metal oxide having a less number of oxygen atoms than metal oxide satisfying the stoichiometric ratio. In some embodiments, the gate insulating layer GI may include a material of which the activation energy for movement of oxygen included in the gate insulating layer GI is 0.6 eV or higher. Because the gate insulating layer GI includes metal oxide that does not satisfy the stoichiometric ratio, the gate insulating layer GI may have oxygen vacancies therein.

The gate electrode GE may be on the gate insulating layer GI. The gate electrode GE may have the same horizontal area as the variable resistance layer RS. The gate electrode GE may include a metal, metal nitride, metal carbide, polysilicon, or a combination thereof. The metal may include, for example, aluminum (Al), W, molybdenum (Mo), titanium (Ti), or tantalum (Ta), the metal nitride may include, for example, titanium nitride or tantalum nitride, and the metal carbide may include, for example, titanium aluminum carbide (TiAlC), tantalum aluminum carbide (TaAlC), titanium silicon carbide (TiSiC), or tantalum silicon carbide (TaSiC).

Existing semiconductor devices using a variable resistance layer use, as a gate insulating layer, oxide (e.g., silicon oxide) that satisfies the stoichiometric ratio. In a semiconductor device using a variable resistance layer, if a positive voltage is applied to a gate electrode to perform a program operation, oxygen vacancies in the variable resistance layer may move to a portion of the variable resistance layer adjacent to an interface where the variable resistance layer is in contact with a channel layer. However, if no voltage is applied to the gate electrode after the program operation, oxygen vacancies dense at the portion of the variable resistance layer adjacent to the interface where the variable resistance layer is in contact with the channel layer due to the positive voltage applied to the gate electrode during the program operation may spread to other portions in the variable resistance layer with a low concentration of oxygen vacancies due to the concentration difference of oxygen vacancies. In this case, the retention characteristic of the semiconductor device may decrease.

However, the semiconductor device 1 according to some embodiments may include the variable resistance layer RS including metal oxide that satisfies the stoichiometric ratio and the gate insulating layer GI including metal oxide that does not satisfy the stoichiometric ratio. If a positive voltage is applied to the gate electrode GE to perform a program operation, oxygen vacancies may move from the gate insulating layer GI including metal oxide that does not satisfy the stoichiometric ratio to the variable resistance layer RS, and thus, the concentration of oxygen vacancies in the variable resistance layer RS may increase, thereby causing the resistance of the variable resistance layer RS to decrease. In this case, even though no voltage is applied to the gate electrode GE after the program operation, the oxygen vacancies in the variable resistance layer RS may not spread to the gate insulating layer GI due to an energy barrier between the variable resistance layer RS and the gate insulating layer GI. Therefore, the retention characteristic of the semiconductor device 1 may be improved.

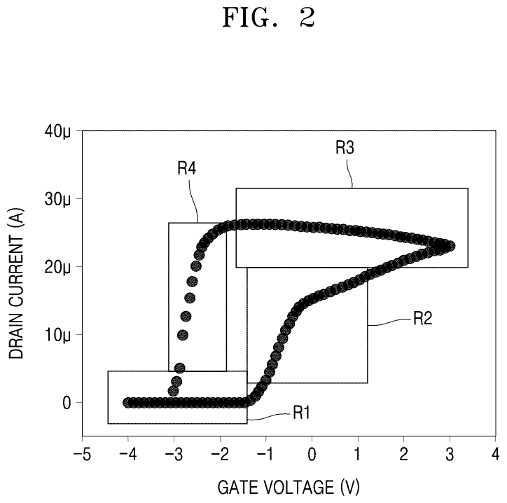

FIG. 2 is a graph obtained by measuring a hysteresis appearing in the semiconductor device 1 of FIG. 1. In FIG. 2, the X axis indicates a voltage applied to the gate electrode GE and the Y axis indicates a drain current according to the applied voltage.

Referring to FIG. 2, in the semiconductor device 1, a hysteresis appears counterclockwise in response to a voltage applied to the gate electrode GE. Particularly, first, in operation R1, a negative voltage may be applied to the gate electrode GE such that both the variable resistance layer RS and the channel layer CH are off and no current flows through a drain. Next, in operation R2, if the voltage applied to the gate electrode GE is higher than a threshold voltage, the channel layer CH may be on and a current flowing through the drain may increase. Next, in operation R3, if the voltage applied to the gate electrode GE further increases, oxygen vacancies may move from the gate insulating layer GI to the variable resistance layer RS, and thus, the resistance of the variable resistance layer RS may be lower than the resistance of the channel layer CH and a current may flow to the drain through the variable resistance layer RS having the lower resistance. Finally, in operation R4, if the negative voltage is applied to the gate electrode GE again, oxygen vacancies in the variable resistance layer RS may move to the gate insulating layer GI, and thus, the channel layer CH and the variable resistance layer RS may be off such that no current flows through the drain.

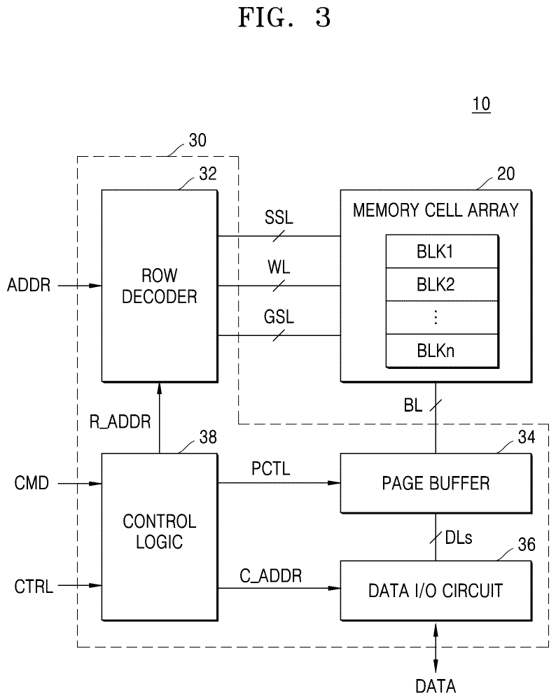

FIG. 3 is a block diagram illustrating a semiconductor device 10 according to some embodiments.

Referring to FIG. 3, the semiconductor device 10 may include a memory cell array 20 and a peripheral circuit 30. The memory cell array 20 includes a plurality of memory cell blocks BLK1, BLK2, . . . , and BLKn. Each of the plurality of memory cell blocks BLK1, BLK2, . . . , and BLKn may include a plurality of memory cells. The plurality of memory cell blocks BLK1, BLK2, . . . , and BLKn may be connected to the peripheral circuit 30 through bit lines BL, word lines WL, string select lines SSL, and ground select lines GSL.

The peripheral circuit 30 may include a row decoder 32, a page buffer 34, a data input-output circuit 36, and a control logic 38. Although not shown in FIG. 3, the peripheral circuit 30 may further include an input-output interface, a column logic, a voltage generator, a pre-decoder, a temperature sensor, a command decoder, an address decoder, an amplification circuit, and the like.

The memory cell array 20 may be connected to the page buffer 34 through the bit lines BL and connected to the row decoder 32 through the word lines WL, the string select lines SSL, and the ground select lines GSL. In the memory cell array 20, each of a plurality of memory cells included in each of the plurality of memory cell blocks BLK1, BLK2, . . . , and BLKn may be a flash memory cell. The memory cell array 20 may include a three-dimensional memory cell array. The three-dimensional memory cell array may include a plurality of NAND strings, and each of the plurality of NAND strings may include a plurality of memory cells vertically stacked on a substrate and connected to a plurality of word lines WL.

The peripheral circuit 30 may receive an address ADDR, a command CMD, and a control signal CTRL from the outside of the semiconductor device 10 and transmit and receive data DATA to and from a device outside the semiconductor device 10.

The row decoder 32 may select at least one of the plurality of memory cell blocks BLK1, BLK2, . . . , and BLKn in response to the address ADDR from the outside and may select a word line WL, a string select line SSL, and a ground select line GSL of the selected memory cell block. The row decoder 32 may provide, to the word line WL of the selected memory cell block, a voltage for performing a memory operation.

The page buffer 34 may be connected to the memory cell array 20 through the bit lines BL. The page buffer 34 may operate as a write driver during a program operation to apply, to the bit lines BL, a voltage according to the data DATA to be stored in the memory cell array 20 and may operate as a sense amplifier during a read operation to sense the data DATA stored in the memory cell array 20. The page buffer 34 may operate in response to a control signal PCTL provided from the control logic 38.

The data input-output circuit 36 may be connected to the page buffer 34 through data lines DLs. During a program operation, the data input-output circuit 36 may receive the data DATA from a memory controller (not shown) and provide the data DATA to the page buffer 34 as program data based on a column address C_ADDR provided from the control logic 38. During a read operation, the data input-output circuit 36 may provide the data DATA stored in the page buffer 34 to the memory controller as read data based on the column address C_ADDR provided from the control logic 38.

The data input-output circuit 36 may provide an input address or instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data input-output circuit 36. The control logic 38 may generate various kinds of internal control signals to be used inside the semiconductor device 10, in response to the control signal CTRL. For example, the control logic 38 may adjust voltage levels to be provided to the word lines WL and the bit lines BL during a memory operation, such as a program operation or an erase operation.

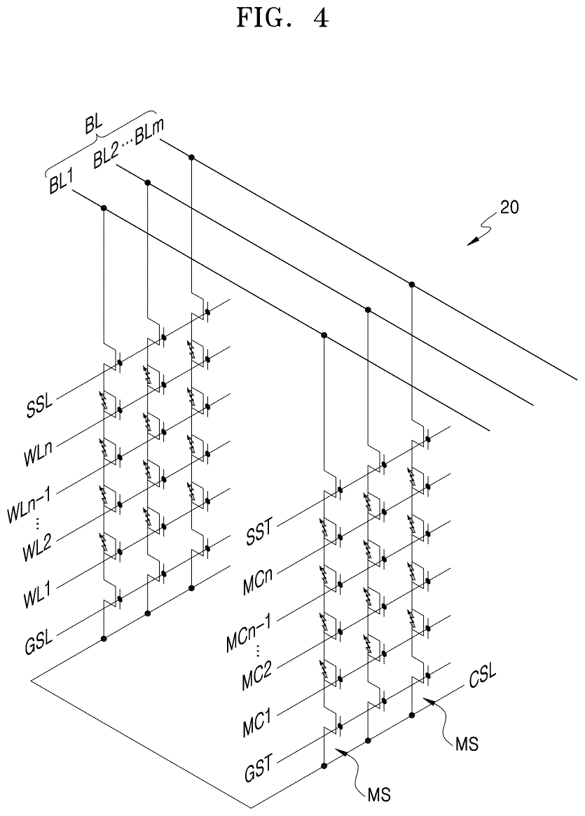

FIG. 4 is an equivalent circuit diagram of the memory cell array 20 in a semiconductor device according to some embodiments.

Referring to FIG. 4, the memory cell array 20 may include a plurality of memory cell strings MS. The memory cell array 20 may include a plurality of bit lines BL (BL1, BL2, . . . , and BLm), a plurality of word lines WL (WL1, WL2, . . . , WLn-1, and WLn), at least one string select line SSL, at least one ground select line GSL, and a common source line CSL. The plurality of memory cell strings MS may be formed between the plurality of bit lines BL (BL1, BL2, . . . , and BLm) and the common source line CSL. Although FIG. 4 shows that each of the plurality of memory cell strings MS includes two string select lines SSL, the technical idea of the inventive concept is not limited thereto. For example, each of the plurality of memory cell strings MS may include one string select line SSL.

Each of the plurality of memory cell strings MS may include a string select transistor SST, a ground select transistor GST, and a plurality of memory cell transistors MC1, MC2, . . . , MCn-1, and MCn. A drain region of the string select transistor SST may be connected to a bit line BL (BL1, BL2, . . . , or BLm), and a source region of the ground select transistor GST may be connected to the common source line CSL. The common source line CSL may be a region to which source regions of a plurality of ground select transistors GST are commonly connected.

The string select transistor SST may be connected to a string select line SSL, and the ground select transistor GST may be connected to a ground select line GSL. The plurality of memory cell transistors MC1, MC2, . . . , MCn-1, and MCn may be connected to the plurality of word lines WL (WL1, WL2, . . . , WLn-1, and WLn), respectively.

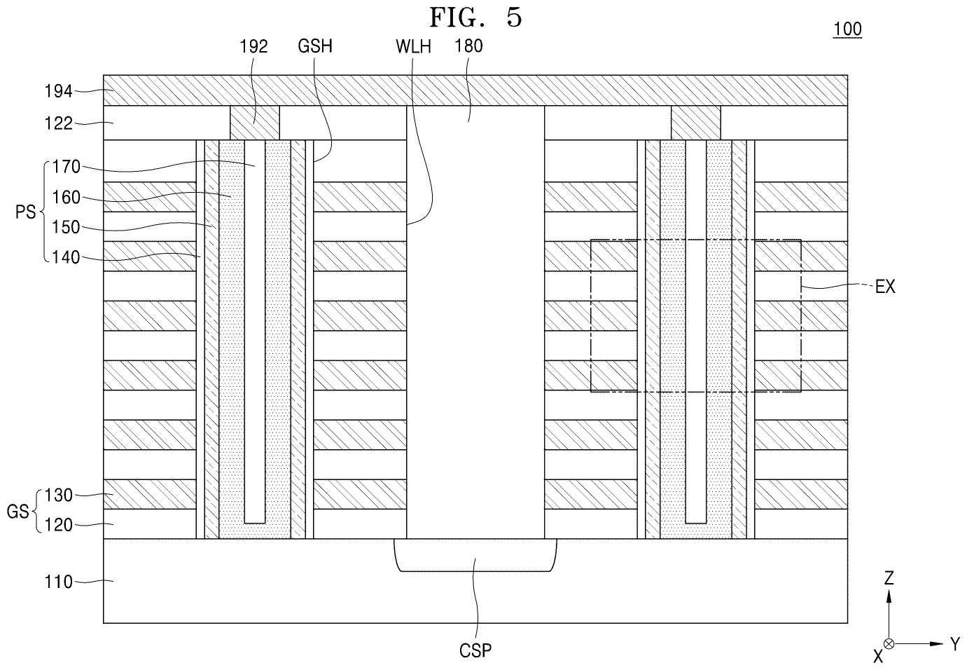

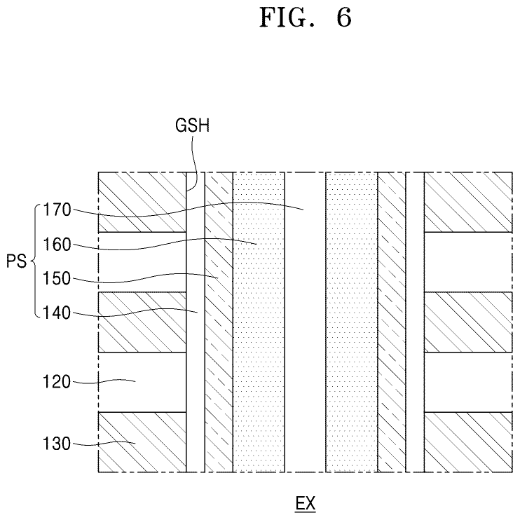

FIG. 5 is a cross-sectional view illustrating a semiconductor device 100 according to some embodiments. FIG. 6 is a magnified cross-sectional view of a portion EX of FIG. 5.

Referring to FIGS. 5 and 6, the semiconductor device 100 may include a substrate 110, a gate stack GS, a pillar structure PS, and a stack separation insulating layer 180.

The substrate 110 may include a semiconductor material, e.g., a Group IV semiconductor, a Group III-V compound semiconductor, or a Group II-VI oxide semiconductor. For example, the Group IV semiconductor may include Si, Ge, or SiGe. The substrate 110 may be provided as a bulk wafer or an epitaxial layer. In some embodiments, the substrate 110 may include a silicon-on-insulator (SOI) substrate or a germanium-on-insulator (GeOI) substrate.

The gate stack GS may be on the substrate 110. The gate stack GS may include a plurality of insulating layers 120 and a plurality of gate electrodes 130 alternately stacked on the substrate 110. The plurality of gate electrodes 130 may be spaced apart from each other in the vertical direction (the Z direction). The plurality of insulating layers 120 may be between two adjacent gate electrodes 130 and between the bottom gate electrode 130 and the substrate 110. The bottom gate electrode 130 among the plurality of gate electrodes 130 may correspond to the ground select line GSL shown in FIG. 4, the top gate electrode 130 among the plurality of gate electrodes 130 may correspond to the string select line SSL shown in FIG. 4, and the remaining gate electrodes 130 among the plurality of gate electrodes 130 may correspond to the plurality of word lines WL shown in FIG. 4. In some embodiments, any one of the plurality of gate electrodes 130 may correspond to a dummy word line (not shown).

In some embodiments, each of the plurality of insulating layers 120 may include silicon oxide, and each of the plurality of gate electrodes 130 may include W, Ti, titanium nitride, Ta, tantalum nitride, or the like.

The gate stack GS may have a through hole GSH extending in the vertical direction (the Z direction) on the substrate 110. The through hole GSH may have a circular-shaped horizontal cross-section and the bottom of the through hole GSH may expose the upper surface of the substrate 110 therethrough.

The pillar structure PS may be in the through hole GSH. The pillar structure PS may include a gate insulating layer 140, a variable resistance layer 150, a channel layer 160, and a buried insulating layer 170.

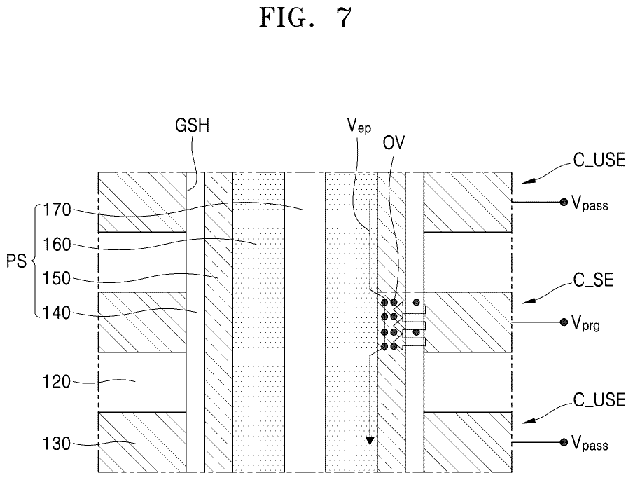

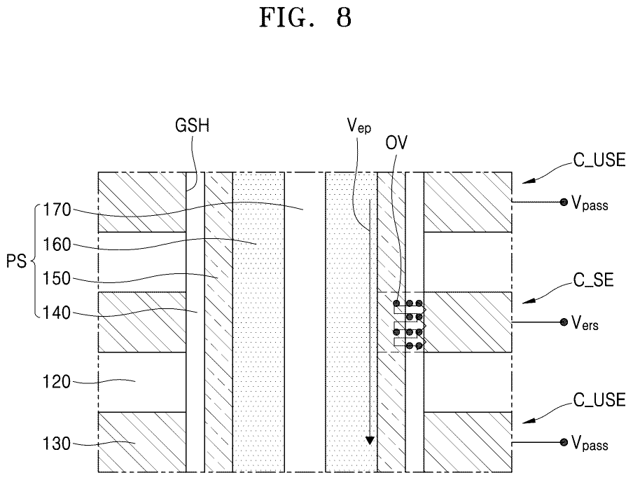

The gate insulating layer 140 may conformally cover, overlap, or be on the inner wall of the through hole GSH. In some embodiments, the gate insulating layer 140 may include metal oxide that does not satisfy the stoichiometric ratio. The metal oxide may include at least one of, for example, rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and/or manganese oxide. For example, the gate insulating layer 140 may include hafnium oxide, where the ratio of hafnium to oxygen in the hafnium oxide is about 1:1.7 and may not satisfy the stoichiometric ratio. That is, the gate insulating layer 140 may include metal oxide having a less or smaller number of oxygen atoms than metal oxide satisfying the stoichiometric ratio. Because the gate insulating layer 140 includes metal oxide that does not satisfy the stoichiometric ratio, according to the magnitude of a voltage applied to a gate electrode 130, oxygen vacancies in the gate insulating layer 140 may move from the gate insulating layer 140 to the variable resistance layer 150 or the moved oxygen vacancies move from the variable resistance layer 150 to the gate insulating layer 140. In some embodiments, the gate insulating layer 140 may include a material of which the activation energy for movement of oxygen included in the gate insulating layer 140 is 0.6 eV or higher. Because the gate insulating layer 140 includes metal oxide that does not satisfy the stoichiometric ratio, the gate insulating layer 140 may have oxygen vacancies therein. As described below with reference to FIG. 7, the oxygen vacancies in the gate insulating layer 140 may move to the variable resistance layer 150 when a positive voltage having a certain value is applied to a gate electrode 130, or as described below with reference to FIG. 8, the moved oxygen vacancies may move from the variable resistance layer 150 to the gate insulating layer 140 when a negative voltage having a certain value is applied to the gate electrode 130.

The variable resistance layer 150 may conformally cover, overlap, or be on the inner wall of the gate insulating layer 140. In some embodiments, the variable resistance layer 150 may include metal oxide that satisfies a stoichiometric ratio. The metal oxide may include at least one of, for example, rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and/or manganese oxide. For example, the variable resistance layer 150 may include tungsten oxide, where the ratio of W to oxygen in the tungsten oxide is about 1:3 and may satisfy the stoichiometric ratio. The internal resistance of the variable resistance layer 150 may vary due to oxygen vacancies moved from the gate insulating layer 140. For example, when oxygen vacancies move from the gate insulating layer 140 to the variable resistance layer 150, the resistance of the variable resistance layer 150 may decrease, and when oxygen vacancies move from the variable resistance layer 150 to the gate insulating layer 140, the resistance of the variable resistance layer 150 may increase. In some embodiments, the variable resistance layer 150 may include a material of which the activation energy for movement of oxygen included in the variable resistance layer 150 is 0.5 eV or lower.

The channel layer 160 may conformally cover, overlap, or be on the inner wall of the variable resistance layer 150 and cover, overlap, or be on the upper surface of the substrate 110 exposed through the bottom of the through hole GSH. In some embodiments, the channel layer 160 may include a metal oxide semiconductor material. For example, the channel layer 160 may include IGZO. The channel layer 160 may include a single layer made of a metal oxide semiconductor material or a plurality of layers made of metal oxide semiconductor materials. Because the channel layer 160 is made of a metal oxide semiconductor material such as IGZO, the off-current of a transistor including the channel layer 160 may decrease and the on/off current ratio of the transistor may increase.

The buried insulating layer 170 may be on the inner wall of the channel layer 160 and fill the inside of the through hole GSH. In some embodiments, the buried insulating layer 170 may be omitted and the channel layer 160 may fill the inside of the through hole GSH. In some embodiments, the buried insulating layer 170 may include silicon oxide.

The gate stack GS may have a stack separation opening WLH penetrating the gate stack GS in the vertical direction (the Z direction) and extending in a horizontal direction. The bottom of the stack separation opening WLH may expose the upper surface of the substrate 110 therethrough, and a common source plate CSP may be in the upper surface of the substrate 110 exposed through the bottom of the stack separation opening WLH. Although not shown in FIG. 5, a common source plug (not shown) electrically connected to the common source plate CSP may be further arranged in the stack separation opening WLH. In some embodiments, the common source plate CSP may include a metal, metal nitride, metal silicide, or the like.

The stack separation insulating layer 180 may be arranged in the stack separation opening WLH. The stack separation insulating layer 180 may include, for example, silicon oxide.

An upper insulating layer 122 may be on the top insulating layer 120. A bit line plug 192 penetrating the upper insulating layer 122 may be on the pillar structure PS, and a bit line 194 electrically connected to the bit line plug 192 may be on the upper insulating layer 122.

Existing semiconductor devices using a variable resistance layer use, as a gate insulating layer, oxide (e.g., silicon oxide) that satisfies the stoichiometric ratio. In a semiconductor device using a variable resistance layer, if a positive voltage is applied to a gate electrode to perform a program operation, oxygen vacancies in the variable resistance layer may move to a portion of the variable resistance layer adjacent to an interface where the variable resistance layer is in contact with a channel layer. However, if no voltage is applied to the gate electrode after the program operation, oxygen vacancies dense at the portion of the variable resistance layer adjacent to the interface where the variable resistance layer is in contact with the channel layer due to the positive voltage applied to the gate electrode during the program operation may spread to other portions in the variable resistance layer with a low concentration of oxygen vacancies due to the concentration difference of oxygen vacancies. In this case, the retention characteristic of the semiconductor device may decrease.

However, the semiconductor device 100 according to some embodiments may include the variable resistance layer 150 including metal oxide that satisfies the stoichiometric ratio and the gate insulating layer 140 including metal oxide that does not satisfy the stoichiometric ratio. If a positive voltage is applied to a gate electrode 130 selected to perform a program operation, oxygen vacancies may move from the gate insulating layer 140 including metal oxide that does not satisfy the stoichiometric ratio to the variable resistance layer 150, and thus, the concentration of oxygen vacancies in the variable resistance layer 150 may increase, thereby causing the resistance of the variable resistance layer 150 to decrease. In this case, even though no voltage is applied to the gate electrode 130 after the program operation, the oxygen vacancies in the variable resistance layer 150 may remain in the variable resistance layer 150 without spreading to the gate insulating layer 140 due to an energy barrier between the variable resistance layer 150 and the gate insulating layer 140. Therefore, the retention characteristic of the semiconductor device 100 may be improved.

FIG. 7 is a cross-sectional view illustrating a program operation of the semiconductor device 100 according to some embodiments.

Referring to FIG. 7, in the program operation of the semiconductor device 100, a pass voltage Vₚₐₛₛ having a positive voltage higher than the threshold voltage may be applied to gate electrodes 130 of unselected cells C_USE to turn on the unselected cells C_USE. In addition, a program voltage V_{prg} having a positive voltage higher than the pass voltage Vₚₐₛₛ may be applied to a gate electrode 130 of a selected cell C_SE such that oxygen vacancies in the gate insulating layer 140 may move to the variable resistance layer 150 by the program voltage V_{prg}. That is, the program voltage V_{prg} may be a positive voltage having a large value enough to move oxygen vacancies in the gate insulating layer 140 to the variable resistance layer 150 and the pass voltage Vₚₐₛₛ may be a positive voltage having a small value enough to turn on the unselected cells C_USE but not enough to move the oxygen vacancies in the gate insulating layer 140 to the variable resistance layer 150. In the selected cell C_SE, because the oxygen vacancies in the gate insulating layer 140 move to the variable resistance layer 150, the concentration of oxygen vacancies in the variable resistance layer 150 may increase and the resistance of the variable resistance layer 150 may be relatively lower than the resistance of the channel layer 160.

In a program state read operation, the pass voltage Vₚₐₛₛ having a positive voltage higher than the threshold voltage may be applied to the gate electrodes 130 of the unselected cells C_USE to turn on the unselected cells C_USE and a read voltage having a voltage lower than the threshold voltage may be applied to the gate electrode 130 of the selected cell C_SE to turn off the selected cell C_SE. Accordingly, in the program state read operation, an electrical path Vₑₚ may be formed such that a current flows along the channel layer 160 in the unselected cells C_USE and flows along the surface of the variable resistance layer 150 adjacent to the channel layer 160 in the selected cell C_SE.

In the program state read operation, the resistance of the variable resistance layer 150 forming the electrical path Vₑₚ in the selected cell C_SE may be relatively lower than the resistance of the channel layer 160. Accordingly, a read current detected in the program state read operation may have a greater value than a set read current value. Herein, the set read current value may indicate a read current detected in a read operation when a program operation or an erase operation is not performed.

FIG. 8 is a cross-sectional view illustrating an erase operation of the semiconductor device 100 according to some embodiments.

Referring to FIG. 8, in the erase operation of the semiconductor device 100, the pass voltage Vₚₐₛₛ having a positive voltage higher than the threshold voltage may be applied to the gate electrodes 130 of the unselected cells C_USE to turn on the unselected cells C_USE. In addition, an erase voltage Vₑᵣₛ that is a negative voltage may be applied to the gate electrode 130 of the selected cell C_SE to turn off the selected cell C_SE. Accordingly, oxygen vacancies in the variable resistance layer 150 may move to the gate insulating layer 140 by the erase voltage Vₑᵣₛ. That is, the erase voltage Vₑᵣₛ may be a negative voltage of which the absolute value is greater than the pass voltage Vₚₐₛₛ, by which the oxygen vacancies in the variable resistance layer 150 move to the gate insulating layer 140, and the pass voltage Vₚₐₛₛ may be a positive voltage having a value that is small enough to turn on the unselected cells C_USE but not enough to move the oxygen vacancies in the gate insulating layer 140 to the variable resistance layer 150. In the selected cell C_SE, because the oxygen vacancies in the variable resistance layer 150 move to the gate insulating layer 140, the concentration of oxygen vacancies in the variable resistance layer 150 may decrease and the resistance of the variable resistance layer 150 may be relatively higher than the resistance of the channel layer 160.

In an erase state read operation, the pass voltage Vₚₐₛₛ having a positive voltage higher than the threshold voltage may be applied to the gate electrodes 130 of the unselected cells C_USE to turn on the unselected cells C_USE and a read voltage having a voltage lower than the threshold voltage may be applied to the gate electrode 130 of the selected cell C_SE to turn off the selected cell C_SE.

Accordingly, in the erase state read operation, the electrical path Vₑₚ may be formed such that a current flows along the channel layer 160 in the unselected cells C_USE and flows along the channel layer 160 of the turned-off selected cell C_SE in the selected cell C_SE.

In the erase state read operation, the resistance of the variable resistance layer 150 forming the electrical path Vₑₚ in the selected cell C_SE may be relatively higher than the resistance of the channel layer 160. Accordingly, a read current detected in the erase state read operation may have a value that is less than the set read current value. Herein, the set read current value may indicate a read current detected in a read operation when a program operation or an erase operation is not performed.

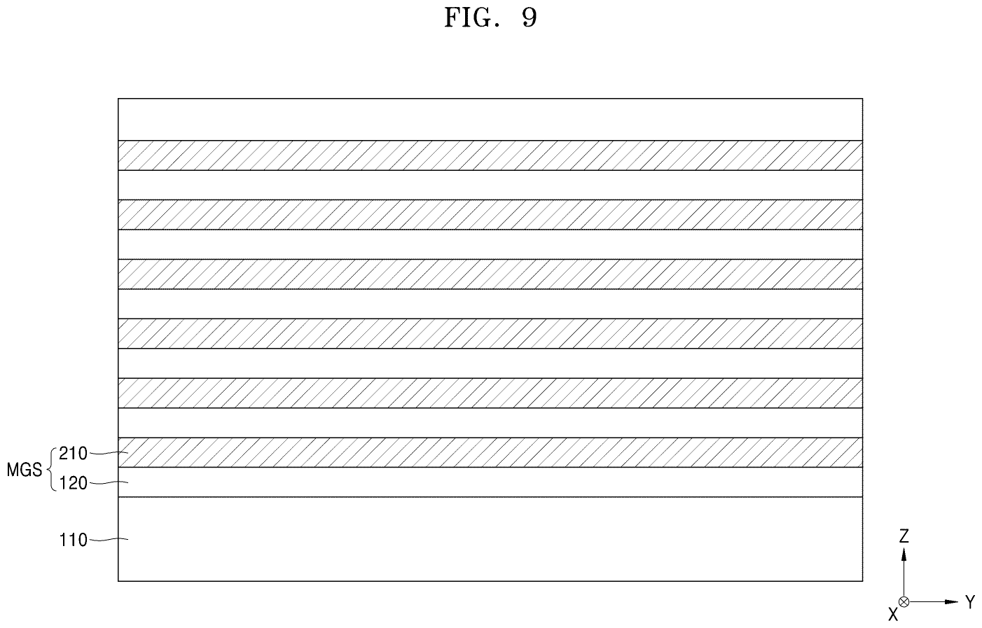

FIGS. 9, 10, 11, and 12 are cross-sectional views illustrating a method of manufacturing the semiconductor device 100 according to some embodiments.

Referring to FIG. 9, a mold gate stack MGS may be formed by alternately stacking the plurality of insulating layers 120 and a plurality of sacrificial layers 210 on the substrate 110. In some embodiments, the plurality of insulating layers 120 may include an insulating material, such as silicon oxide or silicon oxynitride, and the plurality of sacrificial layers 210 may include silicon nitride, silicon oxynitride, impurity-doped polysilicon, or the like.

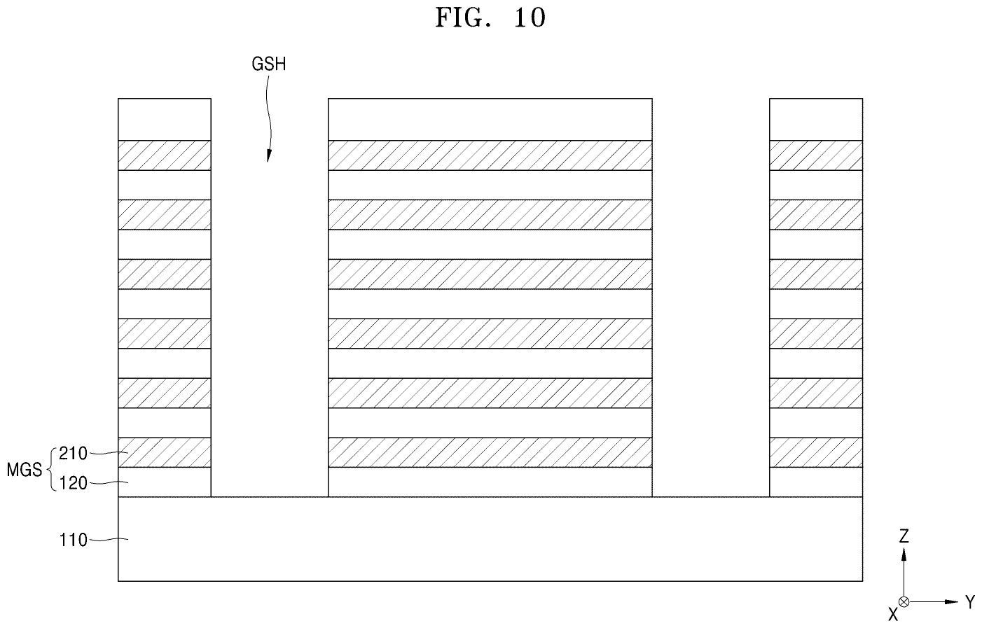

Referring to FIG. 10, in the result of FIG. 9, a mask pattern (not shown) may be formed on the top insulating layer 120 and used as an etching mask to pattern the plurality of insulating layers 120 and the plurality of sacrificial layers 210, thereby forming the through hole GSH.

In some embodiments, the through hole GSH may be formed to have a circular or oval horizontal cross-sectional shape in a top view and may extend in the vertical direction (the Z direction) to expose the upper surface of the substrate 110 therethrough.

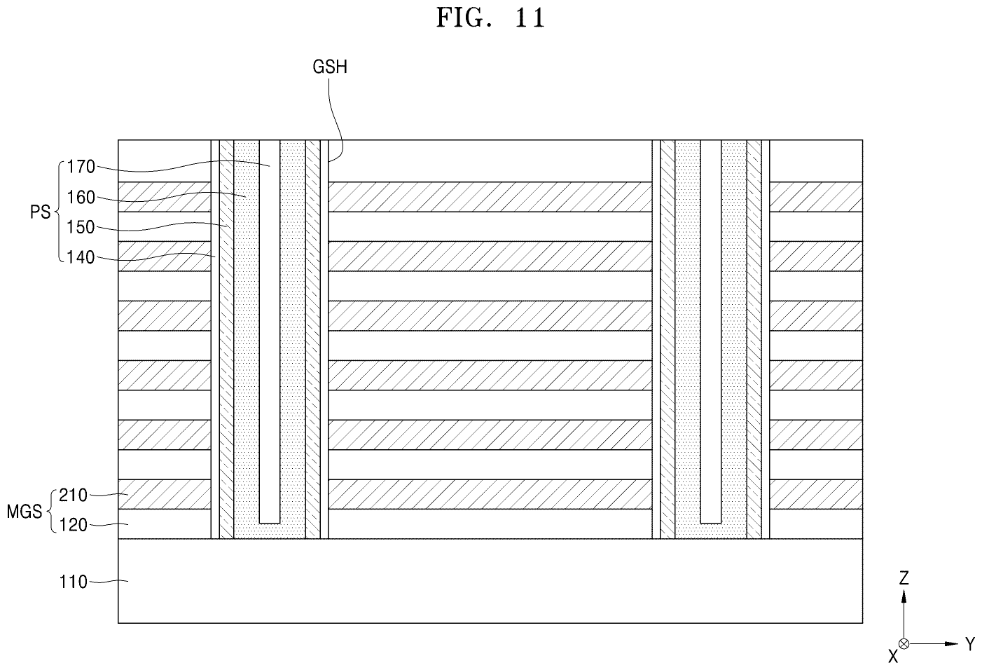

Referring to FIG. 11, in the result of FIG. 10, the pillar structure PS may be formed in the formed through hole GSH. First, the gate insulating layer 140 and the variable resistance layer 150 may be sequentially formed on the inner wall of the through hole GSH. The gate insulating layer 140 may conformally cover, overlap, or be on the inner wall of the through hole GSH and the variable resistance layer 150 may conformally cover, overlap, or be on the inner wall of the gate insulating layer 140. In some embodiments, the gate insulating layer 140 may include metal oxide that does not satisfy the stoichiometric ratio and the variable resistance layer 150 may include metal oxide that satisfies the stoichiometric ratio. For example, the gate insulating layer 140 may include HfOₓ (x is a positive number greater than or equal to 1.7 and less than 2) and the variable resistance layer 150 may include WO₃. In some embodiments, each of the gate insulating layer 140 and the variable resistance layer 150 may be formed by a chemical vapor deposition (CVD) or atomic layer deposition (ALD) process.

Next, the channel layer 160 may be formed on the inner wall of the variable resistance layer 150. The channel layer 160 may cover, overlap, or be on the inner wall of the variable resistance layer 150 and the upper surface of the substrate 110 exposed through the through hole GSH. In some embodiments, the channel layer 160 may include a metal oxide semiconductor material. For example, the channel layer 160 may include IGZO. Next, the buried insulating layer 170 filling the through hole GSH may be formed on the inner wall of the channel layer 160.

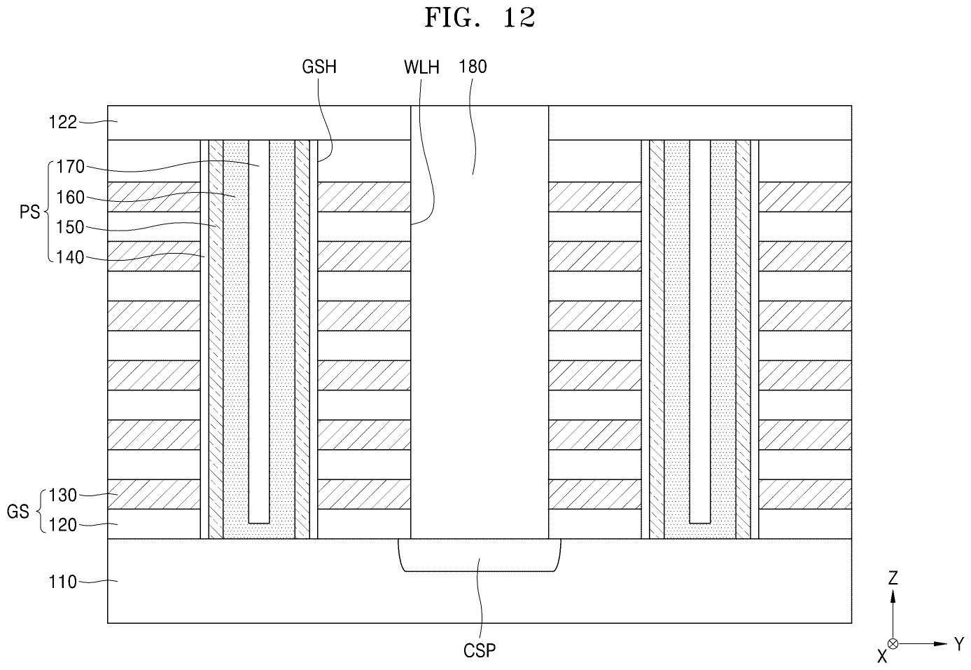

Referring to FIG. 12, in the result of FIG. 11, the upper insulating layer 122 covering or overlapping the top insulating layer 120 and the pillar structure PS may be formed. Next, a portion of the mold gate stack MGS may be removed to form the stack separation opening WLH. In addition, the common source plate CSP may be formed by injecting impurities into a partial region of the substrate 110 exposed through the bottom of the stack separation opening WLH.

Next, the plurality of sacrificial layers 210 (see FIG. 11) exposed through the inner wall of the stack separation opening WLH may be removed and the plurality of gate electrodes 130 may be formed in spaces from which the plurality of sacrificial layers 210 (see FIG. 11) have been removed. A process of removing the plurality of sacrificial layers 210 (see FIG. 11) may include an etching process using an etchant having an etching selectivity with respect to a material constituting the plurality of sacrificial layers 210, and in the etching process, the plurality of insulating layers 120 may be hardly etched. For example, the etching process may be a wet etching process using an etchant including phosphoric acid, but the technical idea of the inventive concept is not limited thereto. Next, the stack separation insulating layer 180 filling the stack separation opening WLH may be formed.

In the result of FIG. 12, the bit line plug 192 penetrating the upper insulating layer 122 and connected to the pillar structure PS may be formed and the bit line 194 may be formed on the upper insulating layer 122. Accordingly, the semiconductor device 100 shown in FIGS. 5 and 6 may be manufactured.

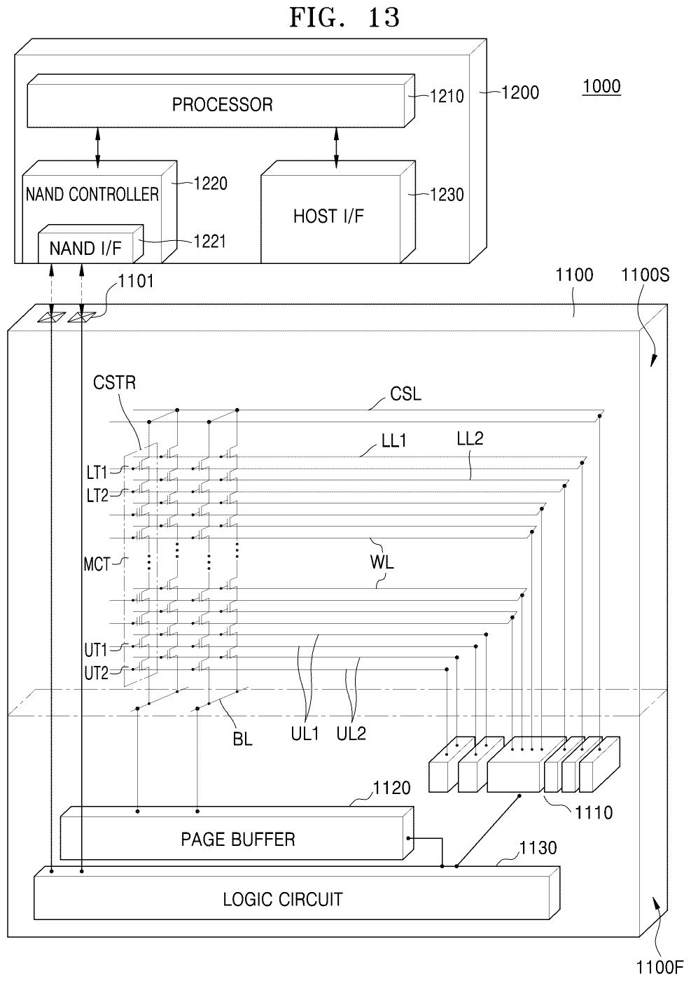

FIG. 13 is a block diagram schematically illustrating an electronic system 1000 including a semiconductor device according to some embodiments.

Referring to FIG. 13, the electronic system 1000 according to some embodiments may include a semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid state drive (SSD) device, a universal serial bus (USB) device, a computing system, a medical device, or a communication device including at least one semiconductor device 1100.

The semiconductor device 1100 may be a nonvolatile memory device. For example, the semiconductor device 1100 may be a NAND flash memory device including at least one of the structures described above with respect to the semiconductor device 100 with reference to FIGS. 5 and 6. The semiconductor device 1100 may include a first structure 1100F and a second structure 1100S on the first structure 1100F. In some embodiments, the first structure 1100F may be beside the second structure 1100S. The first structure 1100F may be a peripheral circuit structure including a decoder circuit 1110, a page buffer 1120, and a logic circuit 1130. The second structure 1100S may be a memory cell structure including the plurality of bit lines BL, the common source line CSL, the plurality of word lines WL, first and second gate upper lines UL1 and UL2, first and second gate lower lines LL1 and LL2, and a plurality of memory cell strings CSTR between the plurality of bit lines BL and the common source line CSL.

In the second structure 1100S, each of the plurality of memory cell strings CSTR may include lower transistors LT1 and LT2 adjacent to the common source line CSL, upper transistors UT1 and UT2 adjacent to a bit line BL, and a plurality of memory cell transistors MCT between the lower transistors LT1 and LT2 and the upper transistors UT1 and UT2. The number of lower transistors (e.g., LT1 and LT2) and the number of upper transistors (e.g., UT1 and UT2) may be variously modified according to some embodiments.

In some embodiments, each of the upper transistors UT1 and UT2 may include a string select transistor and each of the lower transistors LT1 and LT2 may include a ground select transistor. The first and second gate lower lines LL1 and LL2 may be gate electrodes of the lower transistors LT1 and LT2, respectively. The plurality of word lines WL may be gate electrodes of the plurality of memory cell transistors MCT, respectively, and the first and second gate upper lines UL1 and UL2 may be gate electrodes of the upper transistors UT1 and UT2, respectively.

The common source line CSL, the first and second gate lower lines LL1 and LL2, the plurality of word lines WL, and the first and second gate upper lines UL1 and UL2 may be electrically connected to the decoder circuit 1110. The plurality of bit lines BL may be electrically connected to the page buffer 1120.

In the first structure 1100F, the decoder circuit 1110 and the page buffer 1120 may execute a control operation on at least one of the plurality of memory cell transistors MCT. The decoder circuit 1110 and the page buffer 1120 may be controlled by the logic circuit 1130.

The semiconductor device 1100 may communicate with the controller 1200 through input-output pads 1101 electrically connected to the logic circuit 1130. The input-output pads 1101 may be electrically connected to the logic circuit 1130.

The controller 1200 may include a processor 1210, a NAND controller 1220, and a host interface 1230. According to some embodiments, the electronic system 1000 may include a plurality of semiconductor devices 1100, and in this case, the controller 1200 may control the plurality of semiconductor devices 1100.

The processor 1210 may control a general operation of the electronic system 1000 including the controller 1200. The processor 1210 may operate according to certain firmware and control the NAND controller 1220 to access the semiconductor device 1100. The NAND controller 1220 may include a NAND interface 1221 configured to process communication with the semiconductor device 1100. Through the NAND interface 1221, a control command for controlling the semiconductor device 1100, data to be written on the plurality of memory cell transistors MCT in the semiconductor device 1100, data read from the plurality of memory cell transistors MCT in the semiconductor device 1100, and the like may be transferred. The host interface 1230 may provide a communication function between the electronic system 1000 and an external host. When a control command is received from the external host through the host interface 1230, the processor 1210 may control the semiconductor device 1100 in response to the control command.

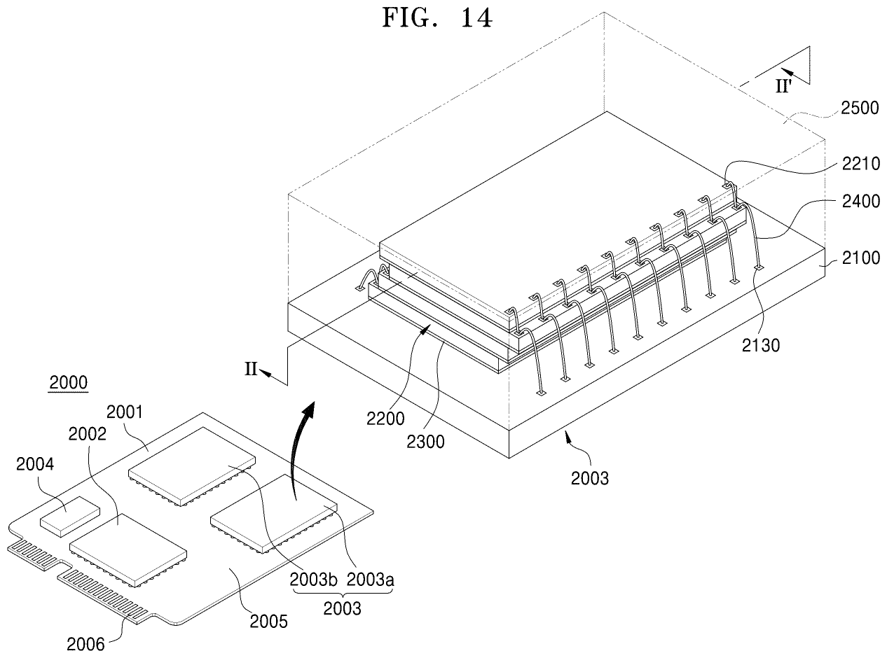

FIG. 14 is a perspective view schematically illustrating an electronic system 2000 including a semiconductor device according to some embodiments.

Referring to FIG. 14, the electronic system 2000 according to some embodiments may include a main substrate 2001 and a controller 2002, a semiconductor package 2003, and dynamic random access memory (DRAM) 2004, which are mounted on the main substrate 2001. The semiconductor package 2003 and the DRAM 2004 may be connected to the controller 2002 through a plurality of wiring patterns 2005 formed on the main substrate 2001.

The main substrate 2001 may include a connector 2006 including a plurality of pins coupled to an external host. The number and the arrangement of pins in the connector 2006 may vary according to a communication interface between the electronic system 2000 and the external host. In some embodiments, the electronic system 2000 may communicate with the external host according to any one of interfaces, such as a USB interface, a peripheral component interconnect express (PCI-Express) interface, a serial advanced technology attachment (SATA) interface, and/or an M-Phy interface for a universal flash storage (UFS). In some embodiments, the electronic system 2000 may operate by power received from the external host through the connector 2006. The electronic system 2000 may further include a power management integrated circuit (PMIC) configured to distribute the power received from the external host to the controller 2002 and the semiconductor package 2003.

The controller 2002 may write or read data on or from the semiconductor package 2003 and improve the operating speed of the electronic system 2000.

The DRAM 2004 may be a buffer memory configured to mitigate the speed difference between the semiconductor package 2003, which is a data storage space, and the external host. The DRAM 2004 included in the electronic system 2000 may operate as a kind of cache memory and provide a space in which data is temporarily stored in a control operation on the semiconductor package 2003. When the DRAM 2004 is included in the electronic system 2000, the controller 2002 may further include a DRAM controller configured to control the DRAM 2004 in addition to a NAND controller configured to control the semiconductor package 2003.

The semiconductor package 2003 may include first and second semiconductor packages 2003a and 2003b separated from each other. Each of the first and second semiconductor packages 2003a and 2003b may include a plurality of semiconductor chips 2200. Each of the first and second semiconductor packages 2003a and 2003b may include a package substrate 2100, the plurality of semiconductor chips 2200 on the package substrate 2100, an adhesive layer 2300 beneath each of the plurality of semiconductor chips 2200, a plurality of connection structures 2400 electrically connecting the plurality of semiconductor chips 2200 to the package substrate 2100, and a molding layer 2500 covering or overlapping the plurality of semiconductor chips 2200 and the plurality of connection structures 2400 on the package substrate 2100.

The package substrate 2100 may be a printed circuit board including a plurality of package upper pads 2130. Each of the plurality of semiconductor chips 2200 may include input-output pads 2210. The input-output pads 2210 may correspond to the input-output pads 1101 of FIG. 13. Each of the plurality of semiconductor chips 2200 may include at least one of the structures described above with respect to the semiconductor device 100 with reference to FIGS. 5 and 6.

In some embodiments, the plurality of connection structures 2400 may be bonding wires electrically connecting the input-output pads 2201 to the plurality of package upper pads 2130. Therefore, in the first and second semiconductor packages 2003a and 2003b, the plurality of semiconductor chips 2200 may be electrically connected to each other by a bonding wire scheme and electrically connected to the plurality of package upper pads 2130 of the package substrate 2100. In some embodiments, in the first and second semiconductor packages 2003a and 2003b, the plurality of semiconductor chips 2200 may be electrically connected to each other through a connection structure including through silicon vias (TSVs) instead of the plurality of connection structures 2400 of the bonding wire scheme.

In some embodiments, the controller 2002 and the plurality of semiconductor chips 2200 may be included in one package. In some embodiments, the controller 2002 and the plurality of semiconductor chips 2200 may be mounted on a separate interposer substrate other than the main substrate 2001, and the controller 2002 may be connected to the plurality of semiconductor chips 2200 through wirings formed on the interposer substrate.

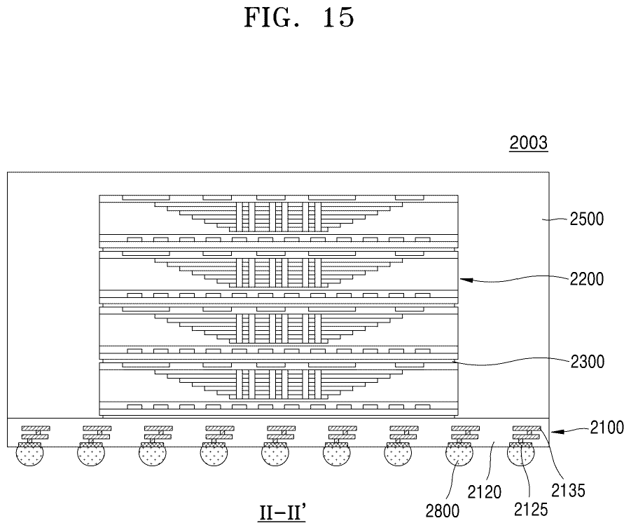

FIG. 15 is a cross-sectional view schematically illustrating the semiconductor package 2003 according to some embodiments. FIG. 15 is a cross-sectional view taken along line II-II′ of FIG. 14.

Referring to FIG. 15, in the semiconductor package 2003, the package substrate 2100 may be a printed circuit board. The package substrate 2100 may include a package substrate body part 2120, the plurality of package upper pads 2130 (see FIG. 14) on the upper surface of the package substrate body part 2120, a plurality of lower pads 2125 disposed on or exposed through the lower surface of the package substrate body part 2120, and a plurality of internal wirings 2135 inside the package substrate body part 2120 to electrically connect the plurality of package upper pads 2130 (see FIG. 14) to the plurality of lower pads 2125. The plurality of package upper pads 2130 may be electrically connected to the plurality of connection structures 2400 (see FIG. 14). The plurality of lower pads 2125 may be connected, through a plurality of conductive connection portions 2800, to the plurality of wiring patterns 2005 on the main substrate 2001 of the electronic system 2000 shown in FIG. 14.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate;
source/drain regions on the substrate;
a channel layer between the source/drain regions and including indium gallium zinc oxide (IGZO);
a variable resistance layer on the channel layer, wherein the variable resistance layer comprises a first metal oxide that satisfies a stoichiometric ratio of metal to oxygen;
a gate insulating layer on the variable resistance layer, wherein the gate insulating layer comprises a second metal oxide that does not satisfy the stoichiometric ratio of metal to oxygen; and
a gate electrode on the gate insulating layer.

2. The semiconductor device of claim 1, wherein the second metal oxide of the gate insulating layer has an activation energy for movement of oxygen included in the gate insulating layer that is greater than or equal to 0.6 eV.

3. The semiconductor device of claim 1, wherein the second metal oxide of the gate insulating layer includes at least one metal oxide among rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and/or manganese oxide, and the at least one metal oxide has oxygen insufficient to satisfy the stoichiometric ratio of metal to oxygen.

4. The semiconductor device of claim 1, wherein the first metal oxide of the variable resistance layer has activation energy for movement of oxygen included in the variable resistance layer that is 0.5 eV or lower.

5. The semiconductor device of claim 1, wherein the first metal oxide of the variable resistance layer includes at least one metal oxide among rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and/or manganese oxide, and the at least one metal oxide satisfies the stoichiometric ratio.

6. The semiconductor device of claim 1, wherein the gate insulating layer includes oxygen vacancies therein, and the oxygen vacancies in the gate insulating layer are configured to move from the gate insulating layer to the variable resistance layer or vice versa responsive to a voltage applied to the gate electrode.

7. The semiconductor device of claim 6, wherein the oxygen vacancies in the gate insulating layer are configured to move to the variable resistance layer such that a resistance of the variable resistance layer is lower than a resistance of the channel layer.

8. A semiconductor device comprising:
a substrate;
a gate stack on the substrate, comprising a plurality of insulating layers and a plurality of gate electrodes alternately stacked in a vertical direction that is perpendicular to a top surface of the substrate, and having a through hole that extends into the plurality of insulating layers and the plurality of gate electrodes in the vertical direction; and
a pillar structure inside the through hole,
wherein the pillar structure comprises:
a gate insulating layer in the through hole and including a first metal oxide that does not satisfy a stoichiometric ratio of metal to oxygen;
a variable resistance layer on an inner wall of the gate insulating layer in the through hole and including a second metal oxide that satisfies the stoichiometric ratio of metal to oxygen;
a channel layer on an inner wall of the variable resistance layer in the through hole and including indium gallium zinc oxide (IGZO); and
a buried insulating layer in a central region of the through hole.

9. The semiconductor device of claim 8, wherein the first metal oxide of the gate insulating layer has an activation energy for movement of oxygen included in the gate insulating layer that is greater than or equal to 0.6 eV.

10. The semiconductor device of claim 8, wherein the first metal oxide of the gate insulating layer includes at least one metal oxide among rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and/or manganese oxide, and the at least one first metal oxide has oxygen insufficient to satisfy the stoichiometric ratio of metal to oxygen.

11. The semiconductor device of claim 8, wherein the second metal oxide of the variable resistance layer has an activation energy for movement of oxygen included in the variable resistance layer that is less than or equal to 0.5 eV.

12. The semiconductor device of claim 8, wherein the second metal oxide of the variable resistance layer includes at least one metal oxide among rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and manganese oxide, and the at least one metal oxide satisfies the stoichiometric ratio of metal to oxygen, wherein the stoichiometric ratio.

13. The semiconductor device of claim 8, wherein the semiconductor device comprises a selected cell and unselected cells and is configured to move oxygen vacancies in the gate insulating layer to the variable resistance layer by responsive to application of a first positive voltage to gate electrodes of the unselected cells and responsive to application of a second positive voltage that is higher than the first positive voltage to a gate electrode of the selected cell.

14. The semiconductor device of claim 13, wherein a resistance of the variable resistance layer to which the oxygen vacancies have moved is less than a resistance of the channel layer.

15. The semiconductor device of claim 8, wherein the semiconductor device comprises a selected cell and unselected cells and is configured to move oxygen vacancies in the variable resistance layer to the gate insulating layer responsive to application of a first positive voltage to gate electrodes of the unselected cells and responsive to application of a first negative voltage to a gate electrode of the selected cell, the first negative voltage having an absolute value that is greater than an absolute value of the first positive voltage.

16. The semiconductor device of claim 15, wherein a resistance of the gate insulating layer to which the oxygen vacancies have moved is greater than a resistance of the channel layer.

17. An electronic system comprising:
a main substrate;
a semiconductor device on the main substrate; and
a controller on the main substrate and electrically connected to the semiconductor device,
wherein the semiconductor device comprises:
a gate stack on a substrate, the gate stack comprising a plurality of insulating layers and a plurality of gate electrodes alternately stacked in a vertical direction that is perpendicular to a top surface of the substrate, and having a through hole that extends into the plurality of insulating layers and the plurality of gate electrodes in the vertical direction; and
a pillar structure in the through hole,
wherein the pillar structure comprises:
a gate insulating layer in the through hole and including a first metal oxide that does not satisfy a stoichiometric ratio of metal to oxygen;
a variable resistance layer on an inner wall of the gate insulating layer in the through hole and including a second metal oxide that satisfies the stoichiometric ratio of metal to oxygen;
a channel layer on an inner wall of the variable resistance layer in the through hole and including indium gallium zinc oxide (IGZO); and
a buried insulating layer in a central region of the through hole.

18. The electronic system of claim 17, wherein the first metal oxide of the gate insulating layer has an activation energy for movement of oxygen included in the gate insulating layer that is greater than or equal to 0.6 eV, and the second metal oxide of the variable resistance layer has an activation energy for movement of oxygen included in the variable resistance layer that is less than or equal to 0.5 eV.

19. The electronic system of claim 17, wherein each of the first metal oxide of the gate insulating layer and the second metal oxide of the variable resistance layer includes at least one metal oxide among rubidium oxide, titanium oxide, barium oxide, calcium oxide, zirconium oxide, hafnium oxide, strontium oxide, scandium oxide, magnesium oxide, lithium oxide, aluminum oxide, silicon oxide, beryllium oxide, niobium oxide, nickel oxide, tantalum oxide, tungsten oxide, vanadium oxide, lanthanum oxide, gadolinium oxide, molybdenum oxide, chromium oxide, and/or manganese oxide.

20. The electronic system of claim 19, wherein the gate insulating layer includes hafnium oxide that does not satisfy the stoichiometric ratio of metal to oxygen, and the variable resistance layer includes tungsten oxide that satisfies the stoichiometric ratio.
